(19) United States
(12) Patent Application Publication
(10) Pub. No.: US 2006/0099827 A1
(43) Pub. Date: May 11, 2006

(54) Photo-enhanced UV treatment of dielectric films

(76) Inventor: Woo Sik Yoo, Palo Alto, CA (US)

Correspondence Address: Tom Chen;MacPHERSON KWOK CHEN & REID LLP, Suite 226, 1762 Technology Drive, San Jose, CA, 95110, US

(21) Appl. No.: 10/982,045

(22) Filed: Nov. 5, 2004

(51) Int. Cl. H01L 21/469; C23C 16/00

(52) U.S. Cl. 438/778; 438/787; 438/795; 118/725; 118/722

(57) ABSTRACT

A dielectric or oxide layer, such as a thin gate oxide, is formed by supplying a wafer in a processing chamber with thermal energy to heat the wafer and light energy, such as ultraviolet light, to improve the quality of the resulting layer.

### BACKGROUND

1. Field of Invention

This invention generally relates to semiconductor manufacturing methods and, more particularly, to a method for treating dielectric films during processing.

2. Related Art

Typical semiconductor devices are manufactured by first providing a bulk material, such as Si, Ge, and GaAs in the form of a semiconductor substrate or wafer. Dopants are then introduced into the substrate to create p- and n-type regions in a process or reaction chamber. The dopants can be introduced using thermal diffusion or ion implantation methods. In the latter method, the implanted ions will initially be distributed interstitially. Thus, to render the doped regions electrically active as donors or acceptors, the ions must be introduced into substitutional lattice sites. This “activation” process is accomplished by heating the bulk wafer, generally in the range of between 600° C. to 1300° C. When using a silicon wafer, for example, a dielectric layer, such as silicon oxide can be “grown” or deposited to provide an electrical interface. Finally a metallization, such as aluminum, is applied using, for example, either evaporation or sputtering technique.

The quality of thin oxides or dielectrics, such as for gate insulating, is becoming more important in the field of semiconductor devices fabrication. Many broad categories of commercial devices, such as electrically erasable programmable read only memories (EEPROMs), dynamic random access memories (DRAMs), and more recently, even high-speed basic logic functions, depend on the ability to reproduce high quality, very thin oxide layers. High quality dielectrics are needed in such devices to achieve satisfactory devices performance both in terms of speed and longevity.

Present gate insulating layers fall short of the requirements necessary for future devices. Most conventional gate insulating layers are pure silicon oxide SiO₂ oxide films formed by thermal oxidation. Others employ a combination of a high temperature deposited SiO₂ layer on a thermally grown layer.

As semiconductor devices and geometries become smaller and smaller, gate oxides need to be thinner and thinner, e.g., on the order of 15 to 20 Å. However, as the oxide layer becomes thinner, tunneling leakage can become a problem, especially with low quality oxides. With current techniques for oxide growth, the quality of the oxide layer is not sufficient to sustain very thin oxide layers. In general, one way to improve oxide layer quality is to increase the temperature or thermal energy at which the oxide is grown. One problem is that as temperature increases, other dopants may diffuse, which may adversely affect other characteristics of the semiconductor device. On the other hand, when thermal energy, which already has relatively low electron energy, is reduced, the thermally grown oxide exhibits poor qualities, due in part to factors such as poor integration and diffusion effects. Thus, it is difficult to form thin oxide layers with consistent quality and thickness using conventional thermal processes.

Pure SiO₂ layers are unsuitable for devices requiring thin or very thin dielectric or oxide films because their integrity is inadequate when formed and they suffer from their inherent physical and electrical limitations. SiO₂ layers also suffer from their inability to be manufactured uniformly and defect-free when formed as these thin layers. Additionally, subsequent VLSI processing steps may continue to degrade the already fragile integrity of thin SiO₂ layers. Furthermore, pure SiO₂ layers tend to degrade when exposed to charge injection, by interface generation and charge trapping. As such, pure SiO₂ layers are inadequate as thin films for future scaled technologies.

In tunnel oxides, breakdowns occur because of the trapping of charge in the oxides, thereby gradually raising the electric field across the oxides until the oxides can no longer withstand the induced voltage. Higher quality oxides trap fewer charges over time and will therefore take longer to break down. Thus, higher quality thin film oxides are desired.

Furthermore, usually oxide films are amorphous, i.e., there is a shortened periodicity, such that oxide atoms in close proximity are similar, but as atoms move farther away, their structure becomes unpredictable. The oxide layer may further have unpaired or dangling bonds. If there is an ion or charge, then dangling bonds may be problematic, resulting, for example, large performance variations between devices.

Thus, it is desirable to make the dangling bonds inactive. One method is to expose the film with the dangling bonds to hydrogen, where the reaction will make the dangling bonds electrically inactive. However, the reaction requires high energy, which can be provided by increasing the temperature or thermal energy. At high temperatures, oxide will grow and would thus undesirably increase the thickness of the “thin” oxide layer.

Therefore, there is a need for methods of forming thin film oxides or dielectrics that overcome the disadvantages of conventional techniques discussed above.

### SUMMARY

According to one aspect of the present invention, light energy, such as ultraviolet (UV) light, is used to irradiate a dielectric or oxide film during and/or between formation of such a film. The additional energy supplied from the light source allows a lower process temperature to form a high quality thin film.

In one embodiment, light having a wavelength between 150 nm and 1 μm is used to irradiate a semiconductor wafer within a process chamber for a time between 0.1 ms and 3600 s, at a temperature between 0° C. and 1300° C. and a pressure between 0.001 mTorr and 1000 Torr to form a thin dielectric film having a thickness between 1 Å and 1000 Å. The irradiation is performed simultaneously with a conventional thin film formation process or can be performed after formation of the film, either in situ or in another chamber. Process gases used with the irradiation may be any gas or gases used in film formation, such as, but not limited to air, O₂, N₂, HCl, NH₃, N₂H₄, and H₂O.

In one embodiment, the process chamber includes a light source, such as a grid lamp or bank of lamps overlying the wafer. The light source is located between a reflector at the top portion of the chamber and the wafer. Light sources may include a halogen lamp, a mercury lamp, or a cadmium lamp that are arranged as a continuous lamp or a series of lamps. In one embodiment, a window is located between the wafer and the light source, where the window can be a filter or a non-filter. A controllable heating source, such as a hot plate, lamps, or susceptor, heats the wafer while process gases are introduced into the chamber. A transport mechanism has the ability to move the wafer into and out of the chamber, as well as within the chamber. The pressure within the process chamber is also adjustable from at least 0.001 mTorr to 1000 Torr. At least one gas inlet/outlet port allows process and other gases to be introduced into and expelled from the chamber. The process chamber can be a single wafer processing chamber or a wafer batch processing chamber.

By using UV light in conjunction with thermal energy, the resulting oxide or dielectric layer can be made as a thin film (e.g., approximately 100 nm or less), while maintaining a high quality level. Lower temperatures may be used, which increases the oxide quality, such as decreasing adverse diffusion effects, charge trapping, and dangling bonds. Electrical properties of the film are also improved. The number of unpaired bonds, such as in a silicon-silicon dioxide interface, are greatly reduced. Other advantages of the present invention include reduction of unwanted electric trap/midgap density of states, reduction of unwanted Si—OH bonds, and reduction of H₂O in the film.

These and other features and advantages of the present invention will be more readily apparent from the detailed description of the preferred embodiments set forth below taken in conjunction with the accompanying drawings.

### BRIEF DESCRIPTION OF THE DRAWINGS

FIG. 1 is a flow chart of one embodiment of the present invention for forming a dielectric layer on a wafer; and

FIG. 2 is a schematic illustration of a side view of an embodiment of a semiconductor wafer processing system for performing the process of FIG. 1.

Embodiments of the present invention and their advantages are best understood by referring to the detailed description that follows. It should be appreciated that like reference numerals are used to identify like elements illustrated in one or more of the figures.

### DETAILED DESCRIPTION

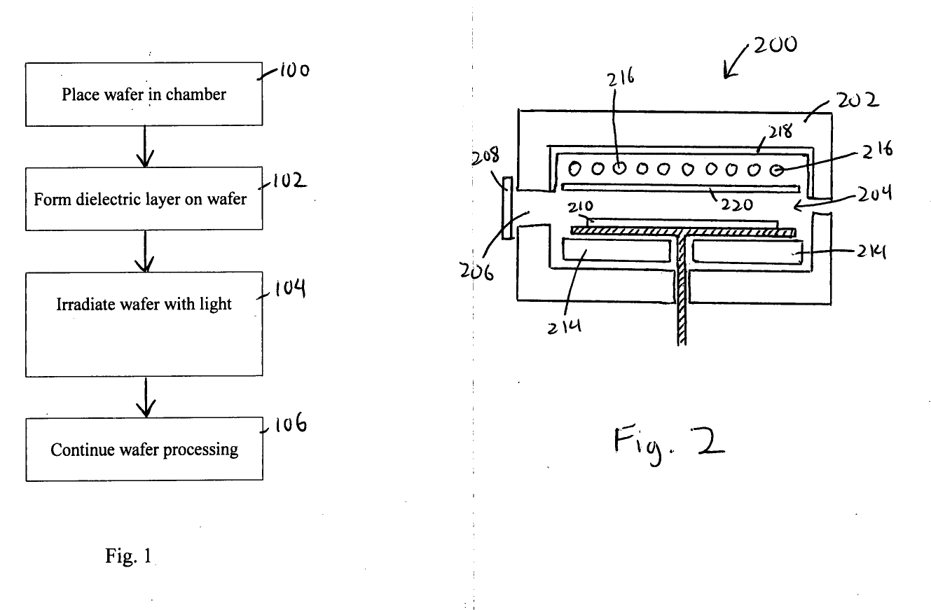

FIG. 1 is a flow chart showing one embodiment of the present invention for forming dielectric films. In step 100, a semiconductor wafer is placed into a process chamber. The wafer can be at different stages of processing, depending on the type of film to be formed on the wafer. In step 102, a dielectric or oxide layer, such as a gate insulating film, is formed on the wafer, such as by introducing one or more process gases into the process chamber. The process gases are used for formation of a dielectric or oxide layer on the wafer. The formation process can be growth or deposition of the oxide layer by chemical vapor deposition (CVD) or physical vapor deposition (PVD) or spin coating using a liquid source. Suitable process gases include, but are not limited to, air, O₂, N₂, HCl, NH₃, and H₂O. Pressure and temperature within the chamber are adjusted depending on the process and system parameters. For example, the pressure may range from 0.001 mTorr to 1000 Torr, and temperature may range from 0° C. to 1300° C. In one embodiment, the temperature is less than 800° C. Because the processes of growing or depositing an oxide layer are well known, specific process parameters will not be given. It should be noted that those skilled in the art will use appropriate process parameters depending on the characteristics needed for the film. One important feature of the present invention is that the temperature does not need to be increased significantly during formation of a thin dielectric film to increase the quality of the film.

In step 104, the wafer is irradiated with light or photon energy. In one embodiment, the irradiation is performed during formation of the dielectric layer. In another embodiment, the irradiation is performed after formation of the dielectric layer or film, such as between film formation cycles for curing. Thus, the light source can be turned off and on during different periods of the film formation and for different durations. For example, the light source can be turned on continuously from the beginning of the film formation process to the end of the process or during any one or more periods in between.

Further, in one embodiment, the irradiation in step 104 can be performed in situ. In other embodiments, the irradiation is performed in a separate process chamber, such as processes in which the wafer is moved from the deposition process chamber to another chamber, either associated with the same machine or in a separate machine. In one embodiment, the light has a wavelength between 150 nm and 1 μm in the visible and ultraviolet (UV) range. UV light, especially, has relatively high energy, i.e., corresponding to 3 eV and higher. After the dielectric layer is formed in steps 102 and 104, processing continues in step 106, as needed for manufacturing the semiconductor device.

FIG. 2 shows a simplified cross-sectional view of a portion of a process reactor 200 in accordance with one embodiment of the present invention. Process reactor 200 includes a shell 202, which can be made of aluminum or other suitable metal, that substantially encloses a process chamber 204, such as a load lock chamber. Process chamber 204 may be formed from a process tube, such as made from quartz, silicon carbide, Al₂O₃, or other suitable material. To conduct a process, process chamber 204 should be capable of being pressurized. Typically, chamber 204 should be able to withstand internal pressures of about 0.001 mTorr to 1000 Torr, preferably between about 0.1 Torr and about 760 Torr. An opening 206 to process chamber 204 is sealable by a gate valve 208. Gate valve 208 is operable to seal opening 206, such as during wafer processing, and to uncover opening 206, such as during wafer transfer into and out of chamber 204. Robot assemblies or other mechanisms (not shown) can be used to transfer a wafer 210, such as from a wafer cassette, to and from the process chamber.

Located within process chamber 204 is a wafer support 212 that supports wafer 210 during processing. Wafer support 212 can be fixed or movable to position the wafer up and down or rotate the wafer within the process chamber. Wafer support 212 can be a plate (as shown), individual standoffs, or any other suitable support. A heat source 214 is also contained within process chamber, such as below wafer 210. Heat source can be any suitable wafer heating source, such as a susceptor, hot plate, or lamps. Lamps may be a single lamp or an array of individual lamps, positioned at distances both from the wafer and from each other to uniformly heat the overlying wafer.

A light source 216 is located above wafer 210 for providing light energy, such as UV energy, to the wafer during processing, as described above. Light source 216 can be one continuous lamp or a bank of lamps. Suitable lamp types include halogen lamps, mercury lamps, xenon lamps, argon lamps, krypton lamps, and cadmium lamps. The choice of light source depends on various factors, including desired light energy. For example, tungsten halogen lamps can be used to provide visible and infrared light. Mercury (Hg) lamps, at low, medium, or high pressure, gives spectral lines, but with different intensity ratio. Lamp activation and operation can be by any suitable conventional method.

The wavelength or frequency of the light can be adjusted, based on various factors, such as the process and type of layer formed. In one embodiment, the wavelength of the light is between 150 nm and 1μm. In order to maximize the amount of light energy incident on wafer 210, a reflector 218 may be located above light source 215 to reflect light back onto wafer 210. Reflector 218 may also be located along the outer periphery of the light source. In different embodiments, reflector 218 may be a separate reflector, such as a mirror, a coating on the inner surface of process chamber 204, or a combination of both. Optionally, a window 220 is located between light source 216 and wafer 210 to allow light to pass, either filtered or unfiltered, to wafer 210 during processing. Accordingly, window 220 can be a filtering window or a non-filtering window, made of materials such as quartz and ZnSe.

Various process chambers and processes can be used with the present invention. For example, the process chamber can be a single wafer chamber for rapid thermal processing or multiple wafer systems. Processing can be thermal annealing, dopant diffusion, thermal oxidation, nitridation, chemical vapor deposition, and similar processes, in which a processing step forms a thin dielectric layer where light energy used during layer formation improves the quality of the resulting layer.

One advantage of using light energy is the high energy levels as compared to thermal energy from conventional heat sources, such as hot plates and susceptors. Because thermal energy has low efficiency, when it is converted to electron energy, the energy level is low. However, light energy, within the visible light spectrum, corresponds to more than 1 eV, while light in the ultraviolet spectrum corresponds to 3 eV or higher. Thus, high energy in the form of light can be supplied to the wafer during processing, in addition to thermal energy. The light does not grow the dielectric or oxide layer, but rather improves the quality of such a layer. Additional advantages include reduction of charge trapping, reduction or elimination of dangling bonds, and improvement of electrical properties of the resulting device.

The above-described embodiments of the present invention are merely meant to be illustrative and not limiting. For example, dielectric or oxide films are discussed here; however, other layers formed during semiconductor processing may also benefit from irradiation with a light source according to the present invention. It will thus be obvious to those skilled in the art that various changes and modifications may be made without departing from this invention in its broader aspects. Therefore, the appended claims encompass all such changes and modifications as fall within the true spirit and scope of this invention.

What is claimed is:

1. A method for processing semiconductor wafers, comprising:
providing a semiconductor substrate in a processing chamber;
providing a process gas within the processing chamber;
heating the substrate during formation of a dielectric layer over the substrate; and
irradiating the substrate with light to improve the quality of the dielectric layer.

2. The method of claim 1, wherein the dielectric layer is an oxide layer.

3. The method of claim 2, wherein the oxide layer is a thin oxide having a thickness between approximately 1 Å and 1000 Å.

4. The method of claim 1, wherein the irradiation is by a light source located above the substrate.

5. The method of claim 1, wherein the light is ultraviolet light.

6. The method of claim 1, wherein the heating is thermal heating.

7. The method of claim 1, further comprising providing a second semiconductor substrate in the processing chamber and heating and irradiating the second substrate during formation of a dielectric layer over the second substrate.

8. The method of claim 1, wherein the heating grows the dielectric layer.

9. The method of claim 1, wherein the irradiating is during formation of the dielectric layer.

10. The method of claim 1, wherein the irradiating is after formation of the dielectric layer.

11. The method of claim 1, further comprising moving the substrate into a second processing chamber after formation of the dielectric layer and prior to irradiating.

12. The method of claim 1, wherein the heating and irradiating are in situ.

13. A method for manufacturing a semiconductor device in a process chamber, the method comprising:
providing a semiconductor substrate in the chamber;
forming a dielectric film over the substrate; and
irradiating the substrate with light to improve the quality of the dielectric film.

14. The method of claim 13, wherein the dielectric layer is an oxide layer.

15. The method of claim 14, wherein the oxide layer is a thin oxide having a thickness between approximately 1 Å and 10,000 Å.

16. The method of claim 13, wherein the irradiation is by a light source located above the substrate.

17. The method of claim 13, wherein the light has a wavelength between approximately 150 nm and 1 μm.

18. The method of claim 13, wherein the forming comprises heating the substrate and introducing at least one process gas in the process chamber.

19. The method of claim 18, wherein the heating is thermal heating.

20. The method of claim 18, wherein the heating grows the dielectric film.

21. The method of claim 13, wherein the irradiating is during the forming.

22. The method of claim 13, wherein the irradiating is after the forming.

23. The method of claim 13, further comprising moving the substrate into a second chamber after the forming and prior to the irradiating.

24. The method of claim 13, wherein the forming and irradiating are in situ.

25. A wafer processing system comprising:
a process chamber;
a gas distribution system configured to introduce a process gas into the chamber;
a wafer support for supporting a wafer during processing;
a heating element positioned below the wafer; and
an irradiating light source positioned above the wafer.

26. The processing system of claim 25, wherein the process gas is selected to form a dielectric layer on the wafer.

27. The processing system of claim 25, wherein the light source is selected from the group consisting of halogen, mercury, xenon, argon, krypton, and cadmium lamps.

28. The processing system of claim 25, wherein the light source comprises a plurality of lamps.

29. The processing system of claim 25, wherein the heating element is a thermal heating element.

30. The processing system of claim 25, further comprising a window between the wafer and the irradiating light source.

31. The processing system of claim 30, wherein the window is a filtering window.

32. The processing system of claim 25, further comprising a reflector located above the irradiating light source.

33. The processing system of claim 25, wherein the heating element and the irradiating light source are configured to both be on during formation of a dielectric layer on the wafer.
